(19) United States
(12) Patent Application Publication
(10) Pub. No.: US 2026/0101771 A1
(43) Pub. Date: Apr. 9, 2026

(54) SEMICONDUCTOR DEVICE AND METHOD OF MANUFACTURING THE SAME

(71) Applicant: Renesas Electronics Corporation, Tokyo (JP)

(72) Inventors: Kenji IKURA, Tokyo (JP); Mitsuo TOKUMARU, Tokyo (JP)

(21) Appl. No.: 19/259,792

(22) Filed: Jul. 3, 2025

(30) Foreign Application Priority Data
Jul. 22, 2024 (JP) 2024-116727

(51) Int. Cl. H01L 23/00; H01L 21/56; H01L 23/31; H01L 23/495

(52) U.S. Cl. CPC H10W 70/417; H10W 70/429; H10W 74/114; H10W 72/075; H10W 72/07533; H10W 72/5525; H10W 72/884; H10W 74/016; H10W 90/736; H10W 90/755

(57) ABSTRACT

A semiconductor device having an improved bonding reliability of wire bonding is provided. The semiconductor device includes a semiconductor chip, a die pad, an inner lead, and a bonding wire. The semiconductor chip has a first lower surface, and a bonding pad provided on a first upper surface. The bonding pad has a second upper surface. The die pad has a third upper surface. The inner lead has a fourth upper surface. The semiconductor chip is mounted on the die pad such that the first lower surface faces the third upper surface. The bonding pad and the inner lead are electrically connected to each other via the bonding wire. In cross-sectional view, the second upper surface, to which the bonding wire is connected, of the bonding pad is located at the same height as the fourth upper surface, to which the bonding wire is connected, of the inner lead.

### CROSS-REFERENCE TO RELATED APPLICATIONS

The disclosure of Japanese Patent Application No. 2024-116727 filed on Jul. 22, 2024, including the specification, drawings and abstract is incorporated herein by reference in its entirety.

### BACKGROUND

This disclosure relates to a semiconductor device and a method of manufacturing a semiconductor device.

There are disclosed techniques listed below.
[Patent Document 1] Japanese Unexamined Patent Application Publication No. 2017-135230
[Patent Document 2] Japanese Unexamined Patent Application Publication No. 2018-107296

The semiconductor device disclosed in Patent Document 1 includes a lead frame including a lead and a die pad, a semiconductor chip, and a bonding wire. The semiconductor chip is mounted on the die pad. The semiconductor chip has a bonding pad provided on an upper surface of the semiconductor chip. An upper surface of the bonding pad and an upper surface of the lead are connected to each other via the bonding wire. The semiconductor device disclosed in Patent Document 2 also has a similar configuration to the semiconductor device disclosed in Patent Document 1.

### SUMMARY

In the semiconductor device disclosed in each of Patent Document 1 and Patent Document 2, the upper surface, to which the bonding wire is connected, of the bonding pad is located at a different height from the upper surface, to which the bonding wire is connected, of the lead. Therefore, in the semiconductor device disclosed in each of Patent Document 1 and Patent Document 2, a connection failure may occur during a wire bonding step. Other problems and novel features will become apparent from the description herein and from the accompanying drawings.

A semiconductor device according to this disclosure includes: a semiconductor chip; a die pad; a lead; and a bonding wire. Here, the semiconductor chip has a first lower surface and a first upper surface opposite the first lower surface. The semiconductor chip has a bonding pad provided on the first upper surface. The bonding pad has a second upper surface. The die pad has a third upper surface. The lead has an outer lead and an inner lead. The inner lead has a fourth upper surface. The inner lead is connected to the outer lead. The semiconductor chip is mounted on the die pad such that the first lower surface faces the third upper surface. The bonding pad and the inner lead are electrically connected to each other via the bonding wire. Also, in cross-sectional view, the second upper surface, to which the bonding wire is connected, of the bonding pad is located at the same height as the fourth upper surface, to which the bonding wire is connected, of the inner lead.

According to the semiconductor device of this disclosure, the bonding reliability of wire bonding can be improved.

### BRIEF DESCRIPTION OF THE DRAWINGS

FIG. 1 is a cross-sectional view of a semiconductor device DEV1.

FIG. 2 is a process flow diagram of a method manufacturing the semiconductor device DEV1.

FIG. 3 is a cross-sectional view explaining a semiconductor chip mounting step S3.

FIG. 4 is a schematic diagram of a bonding apparatus BAP.

FIG. 5 is a first explanatory diagram explaining a wire bonding step S4.

FIG. 6 is a second explanatory diagram explaining the wire bonding step S4.

FIG. 7 is a third explanatory diagram explaining the wire bonding step S4.

FIG. 8 is a fourth explanatory diagram explaining the wire bonding step S4.

FIG. 9 is a cross-sectional view of a semiconductor device DEV2.

FIG. 10 is a first explanatory diagram explaining a wire bonding step S4 in a method of manufacturing the semiconductor device DEV2.

FIG. 11 is a second explanatory diagram explaining the wire bonding step S4 in the method of manufacturing the semiconductor device DEV2.

FIG. 12 is a cross-sectional view of a semiconductor device DEV3 according to a modified example.

FIG. 13 is a cross-sectional view of a semiconductor device DEV4.

### DETAILED DESCRIPTION

The details of the embodiments of this disclosure will be described with reference to the drawings. In the following drawings, the same reference numerals are used for the same or corresponding parts, and redundant explanations are not repeated.

### First Embodiment

The semiconductor device according to the first embodiment will be described.

### <Configuration of Semiconductor Device DEV1>

The configuration of the semiconductor device DEV1 will be described below.

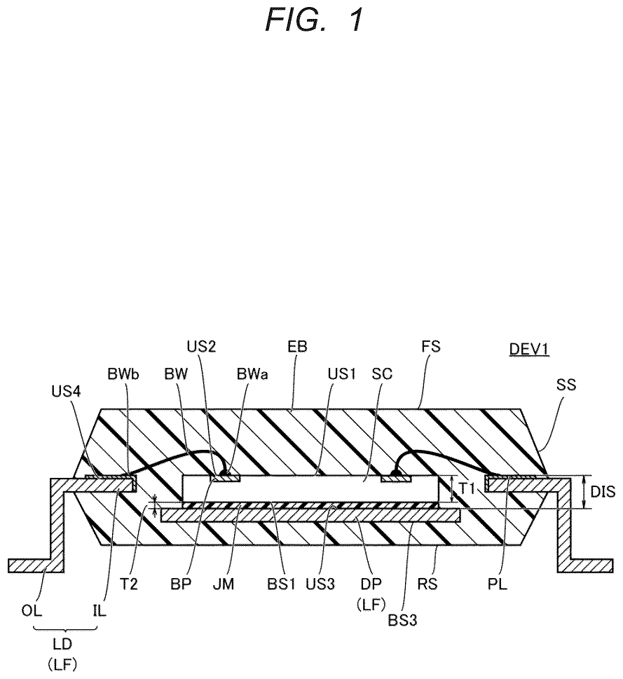

As shown in FIG. 1, the semiconductor device DEV1 includes a semiconductor chip SC, a lead frame LF, a bonding material JM, a bonding wire BW, and a sealing body EB.

The semiconductor chip SC has an upper surface US1 and a lower surface BS1 opposite the upper surface US1. The semiconductor chip SC has a bonding pad BP provided on the upper surface US1. The bonding pad BP has an upper surface US2. The bonding pad BP is made of, for example, aluminum or an aluminum alloy.

The lead frame LF includes a die pad DP and a plurality of leads LD. The die pad DP has an upper surface US3. Each of the leads LD include an outer lead OL and an inner lead IL. The inner lead IL has an upper surface US4 and is connected to the outer lead OL. The lead frame LF is made of, for example, a copper alloy. A plating film PL may be formed on the upper surface US3.

The semiconductor chip SC is mounted on the die pad DP such that the lower surface BS1 faces the upper surface US3. A bonding material JM is interposed between the semiconductor chip SC (lower surface BS1) and the die pad DP (upper surface US3). The bonding material JM is made of, for example, an adhesive.

The bonding wire BW has an end portion BWa and an end portion BWb opposite the end portion BWa. The upper surface US2 of the bonding pad BP and the upper surface US4 of the inner lead IL are electrically connected to each other via the bonding wire BW. More specifically, the bonding wire BW is connected to the upper surface US2 of the bonding pad BP at the end portion BWa thereof and connected to the upper surface US4 of the inner lead IL at the end BWb thereof. The bonding wire BW is made of, for example, copper or a copper alloy. The bonding wire BW may also be formed of gold, a gold alloy, silver, or a silver alloy.

The sealing body EB has a front surface FS, a rear surface RS opposite the front surface FS, and a side surface SS located between the front surface FS and the rear surface RS. The sealing body EB seals the semiconductor chip SC, the die pad DP, the inner lead IL, and the bonding wire BW. However, the outer lead OL protrudes from the side surface SS of the sealing body EB. The sealing body EB is made of, for example, epoxy resin. The outer lead OL has, for example, a gull-wing shape. The outer lead OL may have a J-shape. The semiconductor device DEV1 is, for example, a package of QFP (Quad Flat Package), PLCC (Plastic Leaded Chip Carrier), SOP (Small Outline Package), or SOJ (Small Outline J-leaded) type.

As shown in FIG. 1, the upper surface US2, to which the bonding wire BW (end portion BWa) is connected, of the bonding pad BP is located at the same height as the upper surface US4, to which the bonding wire BW (end portion BWb) is connected, of the inner lead IL. In cross-sectional view, if the height difference between the upper surface US2 to which the bonding wire BW is connected and the upper surface US4 to which the bonding wire BW is connected is 90 μm or less, the upper surface US2, to which the bonding wire BW is connected, of the bonding pad BP is considered to be at the same height as the upper surface US4, to which the bonding wire BW is connected, of the inner lead IL.

### <Method of Manufacturing Semiconductor Device DEV1>

The method of manufacturing of the semiconductor device DEV1 will be described below.

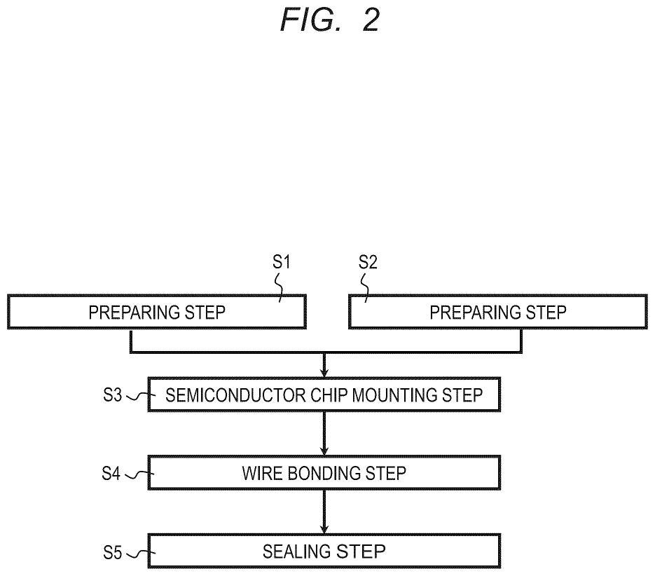

As shown in FIG. 2, the method of manufacturing the semiconductor device DEV1 includes a preparing step S1, a preparing step S2, a semiconductor chip mounting step S3, a wire bonding step S4, and a sealing step S5.

In the preparing step S1, the semiconductor chip SC is prepared. In the preparing step S2, the lead frame LF is prepared. However, at this stage, the gull-wing shape of the outer lead OL is not formed. After the preparing steps S1 and S2, the semiconductor chip mounting step S3 is performed.

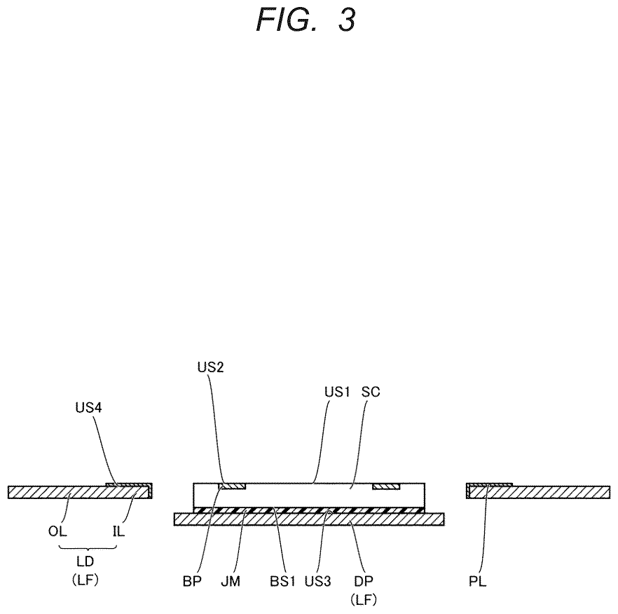

As shown in FIG. 3, in the semiconductor chip mounting step S3, the semiconductor chip SC is mounted on the die pad DP. In the semiconductor chip mounting step S3, first, the bonding material JM is applied on the upper surface US3 of the die pad DP. Second, the semiconductor chip SC is disposed on the die pad DP such that the lower surface BS1 faces the upper surface US3 via the bonding material JM. Third, heating (heat treatment) is performed to bond the semiconductor chip SC and the die pad DP to each other by using the bonding material JM. As a result, the semiconductor chip SC is mechanically connected to the die pad DP. After the semiconductor chip mounting step S3, the wire bonding step S4 is performed.

In the wire bonding step S4, the upper surface US2 of the bonding pad BP and the upper surface US4 of the inner lead IL are electrically connected to each other via the bonding wire BW.

The thickness of the semiconductor chip SC is denoted as thickness T1, and the thickness of the bonding material JM is denoted as thickness T2 (see FIG. 1). The height difference between the upper surface US4, to which the bonding wire BW (end portion BWb) is connected, of the inner lead IL and the upper surface US3 of the die pad DP is denoted as distance DIS (see FIG. 1). In the preparing step S1, the semiconductor chip SC is selected such that the sum of thickness T1 and thickness T2 (i.e., total thickness) is equal to the distance DIS. The thickness T1 of the semiconductor chip SC is adjusted, for example, by the amount of polishing on the lower surface BS1 thereof. The thickness T2 of the bonding material JM is adjusted, for example, by the applied amount of bonding material JM onto the upper surface US3 of the die pad DP. In the preparing step S2, the lead frame LF is selected such that the distance DIS is equal to the sum of thickness T1 and thickness T2 (i.e., total thickness). The distance DIS is adjusted, for example, by the amount of pressing when forming the die pad DP, or in other words, by the amount of bending (offset amount) of the suspension lead (not shown) supporting the die pad DP. This allows the upper surface US2, to which the bonding wire BW is connected, of the bonding pad BP to be located at the same height as the upper surface US4, to which the bonding wire BW is also connected, of the inner lead IL.

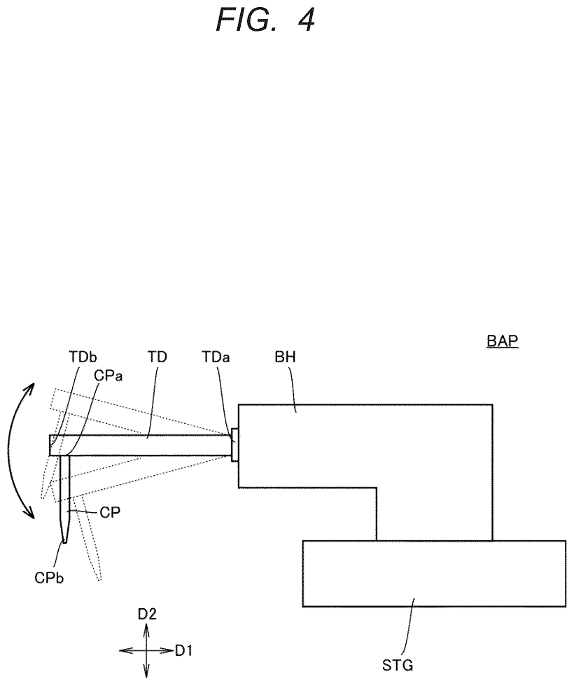

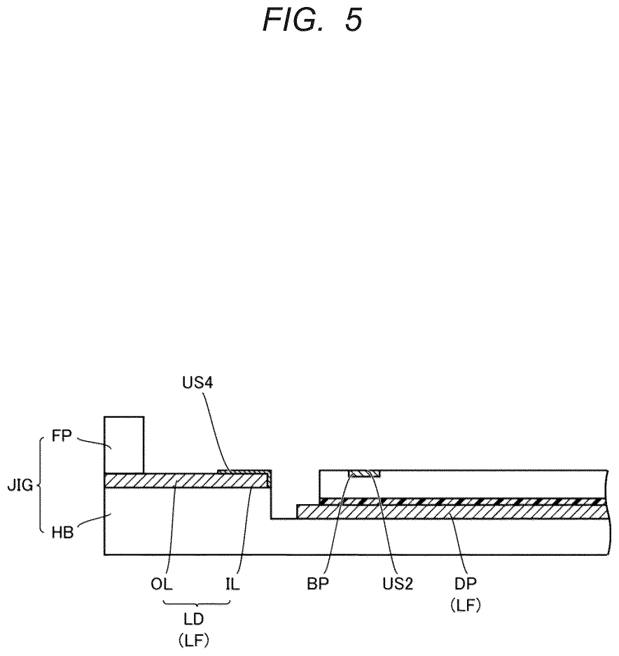

More specifically, the wire bonding step S4 is performed by using a bonding apparatus BAP. As shown in FIG. 4, the bonding apparatus BAP includes a stage STG, a bonding head BH, a transducer TD, and a capillary CP. The bonding head BH is provided on the stage STG. The stage STG is an XY stage. The stage STG is capable to move the bonding head BH in a horizontal plane. However, the stage STG cannot move the bonding head BH in a direction perpendicular to the horizontal plane. Note that in FIGS. 5 to 8, the stage STG and the bonding head BH of the bonding apparatus BAP are not shown.

The transducer TD has an end portion TDa and an end portion TDb. The end portion TDb is located on the opposite side of the end portion TDa. The transducer TD is connected to the bonding head BH at the end portion TDa. The bonding head BH can move the end portion TDb in an arc motion. The capillary CP has an end portion CPa and an end portion CPb. The end portion CPb is located on the opposite side of the end portion CPa. The capillary CP is attached to the end portion TBb of the transducer TD at the end portion CPa. The capillary CP holds the bonding wire BW at the end portion CPb.

In the wire bonding step S4, first, as shown in FIG. 5, the lead frame LF, in which the semiconductor chip SC is mounted on the die pad DP, is held by a holding jig JIG. The holding jig JIG includes a heater block HB and a frame presser FP. The lead frame LF is placed on the heater block HB and pressed against the heater block HB by the frame presser FP. Thus, the lead frame LF is held by the holding jig JIG. The heater block HB heats the semiconductor chip SC and the lead frame LF during the wire bonding step S4.

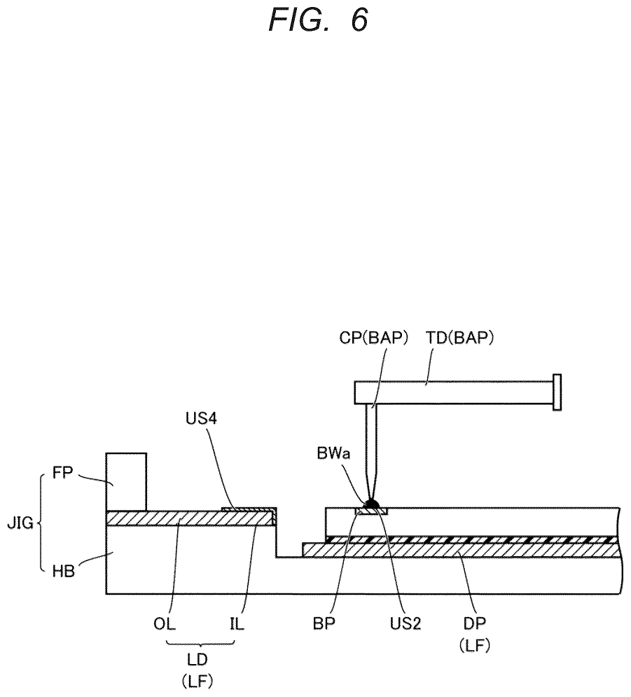

Second, as shown in FIG. 6, the end portion BWa is connected to the upper surface US2. The connection of the end portion BWa to the upper surface US2 is performed by applying an ultrasonic wave to a bonding interface between the end portion BWa and the upper surface US2 while the end portion BWa is in contact with the upper surface US2. This ultrasonic wave is generated by applying a voltage to a piezoelectric element built into the transducer TD, causing the transducer TD to vibrate, and is applied to the bonding interface through the capillary CP. When the ultrasonic wave is applied to the bonding interface between the end portion BWa and the upper surface US2, alloying occurs at the bonding interface, and bonding is achieved. At this time, the extending direction of the capillary CP is parallel to the normal direction (direction D2 in FIG. 4) of the horizontal plane (direction D1 in FIG. 4) in which the bonding head BH moves. That is, at this time, the capillary contact angle formed by the extending direction of the capillary CP and the upper surface US2 is 90°. If the angle formed by the extending direction of the capillary CP and the normal direction of the horizontal plane in which the bonding head BH moves is within the range of 90°±0.5°, it is considered that the extending direction of the capillary CP and the normal direction of the horizontal plane in which the bonding head BH moves are parallel (capillary contact angle is 90°).

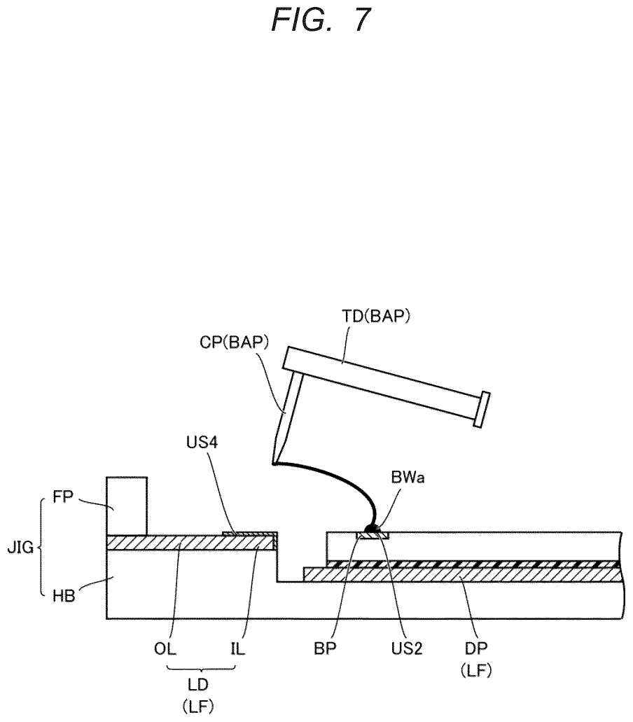

Third, as shown in FIG. 7, the stage STG moves the bonding head BH until the end portion BWb of the bonding wire BW held by the capillary CP is located on the upper surface US4. At this time, the bonding head BH moves the end portion TDb of the transducer TD in an arc motion to incline the extending direction of the capillary CP relative to the normal direction of the horizontal plane in which the bonding head BH moves, thereby raising the position of the end portion BWb and forming a loop of the bonding wire BW. When the end portion BWb has moved onto the upper surface US4, the bonding head BH returns the extending direction of the capillary CP to a state that is parallel to the normal direction of the horizontal plane in which the bonding head BH moves.

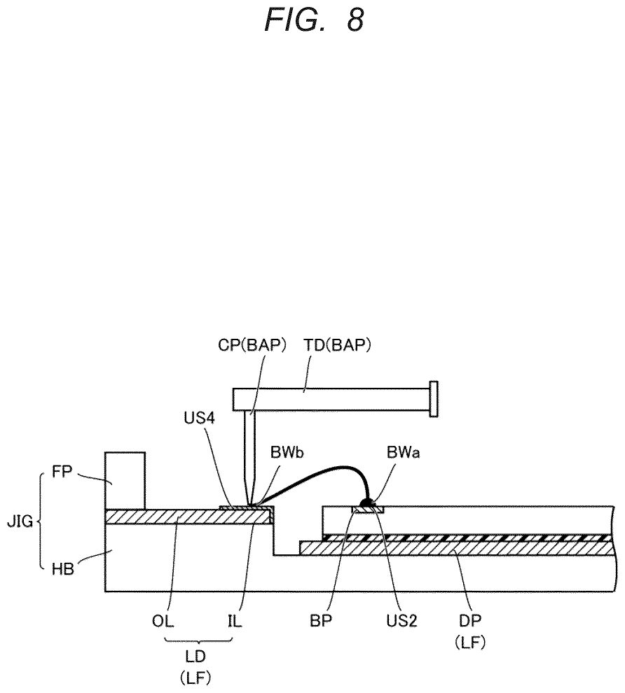

Fourth, as shown in FIG. 8, the ultrasonic wave is applied to the bonding interface between the end portion BWb and the upper surface US4 while the end portion BWa is in contact with the upper surface US2. At this time, the extending direction of the capillary CP is parallel to the normal direction of the horizontal plane in which the bonding head BH moves. That is, at this time, the capillary contact angle formed by the extending direction of the capillary CP and the upper surface US4 is 90°. After the wire bonding step S4, the sealing step S5 is performed. In the sealing step S5, for example, by the transfer molding method, the sealing body EB is formed to seal the semiconductor chip SC, the die pad DP, the inner lead IL, and the bonding wire BW. After the sealing step S5 is performed, a bending step is performed on the outer lead OL, and the outer lead OL is formed into the gull-wing shape. In this way, the structure of the semiconductor device DEV1 shown in FIG. 1 is formed.

### <Effect of Semiconductor Device DEV1>

The effect of the semiconductor device DEV1 will be described below in comparison with the semiconductor device DEV2 according to a comparative example studied by the present inventor.

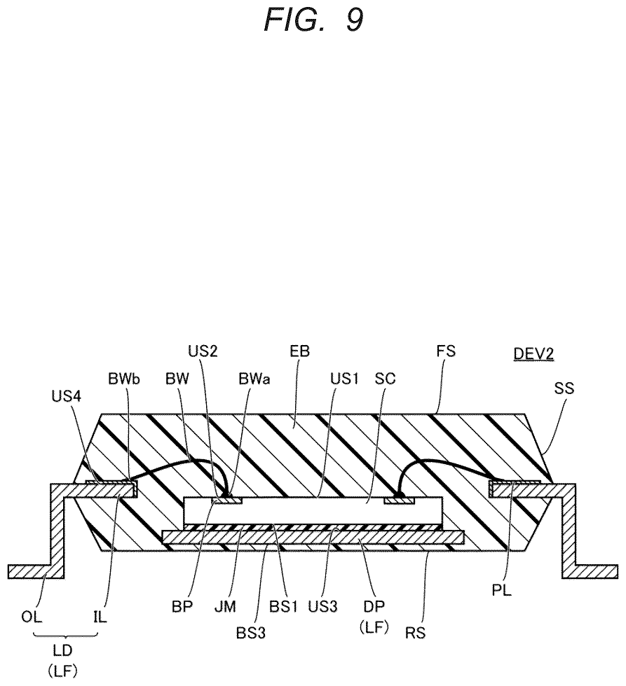

As shown in FIG. 9, the semiconductor device DEV2 includes a lead frame LF, a semiconductor chip SC, a bonding wire BW, and a sealing body EB. In this regard, the configuration of the semiconductor device DEV2 is common with the configuration of the semiconductor device DEV1.

However, in the semiconductor device DEV2, as shown in FIG. 9, the upper surface US2, to which the bonding wire BW is connected, of the bonding pad BP is not located at the same height as the upper surface US4, to which the bonding wire BW is connected, of the inner lead IL. More specifically, in the semiconductor device DEV2, the upper surface US2 to which the bonding wire BW is connected is located lower than the upper surface US4 to which the bonding wire BW is connected. In this regard, the configuration of the semiconductor device DEV2 differs from the configuration of the semiconductor device DEV1.

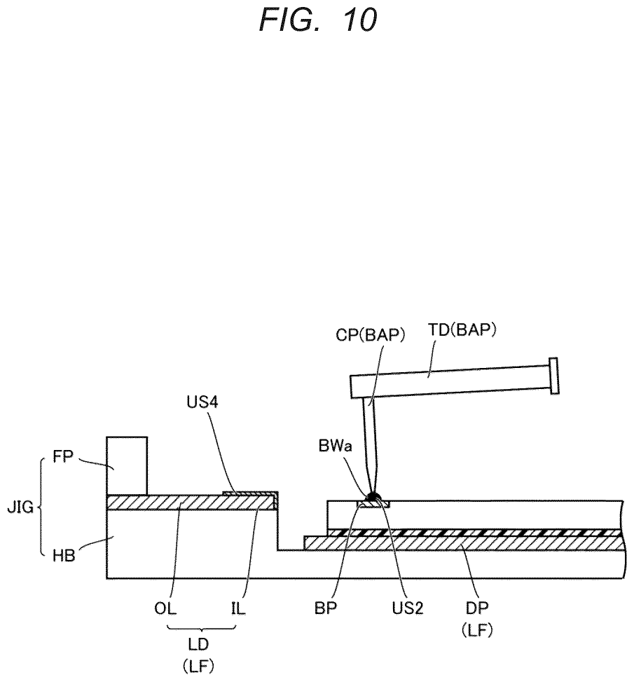

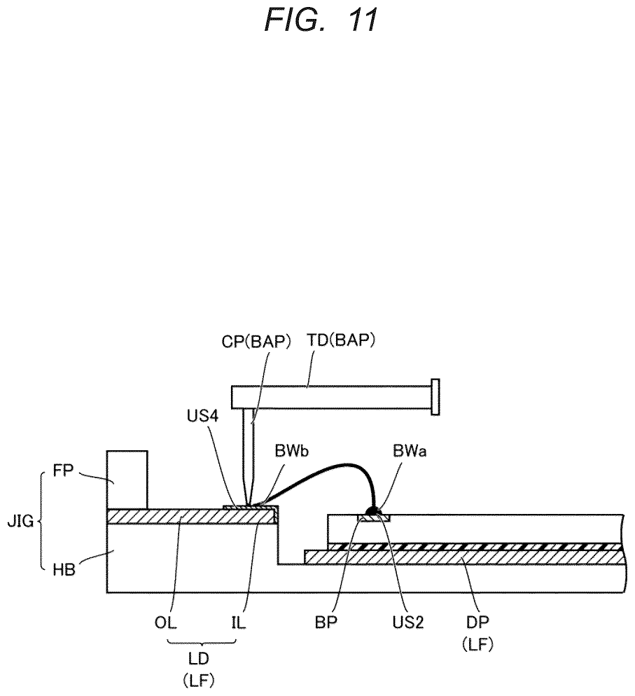

As shown in FIGS. 10 and 11, in a method of manufacturing the semiconductor device DEV2, the stage STG cannot move the bonding head BH in a direction perpendicular to the horizontal plane. Therefore, as shown in FIG. 11, if the capillary contact angle when connecting the end portion BWb to the upper surface US4 is adjusted to 90°, the capillary contact angle when connecting the end portion BWa to the upper surface US2 cannot be made 90°. If the capillary CP is inclined with respect to the upper surface US2, the ultrasonic wave is not uniformly supplied (applied) to the bonding interface. As a result, alloying is less likely to progress at the bonding interface, and a sufficient bonding area cannot be obtained, resulting in insufficient bonding reliability. This becomes more pronounced when the bonding wire BW is made of copper or a copper alloy, as diffusion for alloying becomes less likely to occur. Although not shown, if the capillary contact angle when connecting the end portion BWa to the upper surface US2 is adjusted to 90°, similar connection defects will occur at the bonding interface between the end portion BWb and the upper surface US4.

On the other hand, in the semiconductor device DEV1, the upper surface US2, to which the bonding wire BW is connected, of the bonding pad BP is located at the same height as the upper surface US4, to which the bonding wire BW is connected, of the inner lead IL. Therefore, in the semiconductor device DEV1, both the capillary contact angle when connecting the end portion BWa to the upper surface US2 of the bonding pad BP and the capillary contact angle when connecting the end portion BWb to the upper surface US4 of the inner lead IL can be made 90°, resulting in good bonding at both the interface between the end portion BWa and the upper surface US2 and the interface between the end portion BWb and the upper surface US4, thereby the bonding reliability of the wire bonding is improved.

### <Modified Example>

A modified example of the semiconductor device DEV1 will be described below.

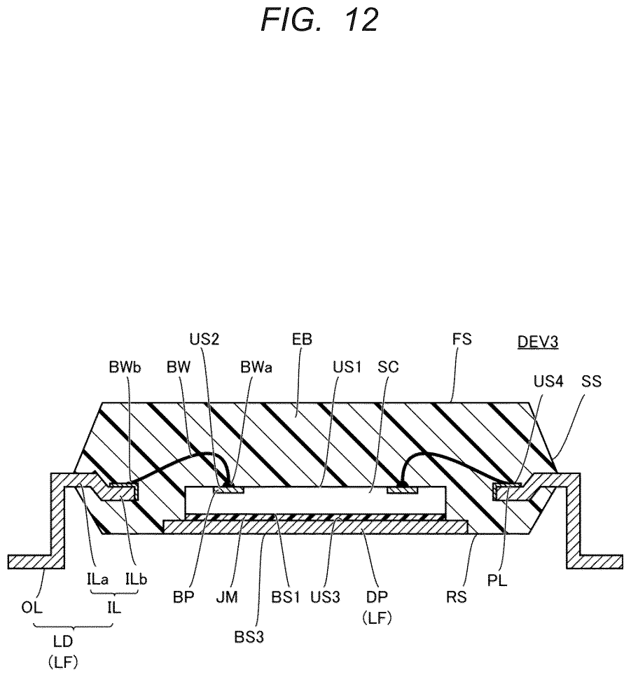

As a modified example of the semiconductor devices DEV1 and DEV2, a semiconductor device DEV3 is shown in FIG. 12. As shown in FIG. 12, the semiconductor device DEV3 includes a lead frame LF, a semiconductor chip SC, a bonding wire BW, and a sealing body EB. In this regard, the configuration of the semiconductor device DEV3 is common with the configuration of the semiconductor device DEV1. However, in the semiconductor devices DEV1 and DEV2, as shown in FIGS. 1 to 9, the lower surface BS3 of the die pad DP is covered by the sealing body EB, whereas in the semiconductor device DEV3, as shown in FIG. 12, the lower surface BS3 of the die pad DP is exposed from the sealing body EB at the rear surface RS of the sealing body EB. Therefore, the upper surface US1 of the semiconductor chip SC of the semiconductor device DEV3 is located lower than the upper surface US1 of the semiconductor chip SC of each of the semiconductor devices DEV1 and DEV2 (see FIGS. 1, 9, and 12).

Furthermore, as shown in FIG. 12, the inner lead IL has a base end portion ILa and a tip end portion ILb. The base end portion ILa is connected to the outer lead OL. The tip end portion ILb is positioned on the distal side of the inner lead IL. The tip end portion ILb is located lower than the base end portion ILa. That is, the tip end portion ILb is located closer to the rear surface RS of the sealing body EB than the base end portion ILa. The bonding wire BW (end portion BWb) is connected to the upper surface US4 in the tip end portion ILb. That is, the upper surface US4 located in the tip end portion ILb is located at the same height as the upper surface US2, to which the bonding wire BW (end portion BWa) is connected, of the bonding pad BP. The tip end portion ILb located lower than the base end portion ILa is obtained, for example, by performing a bending process to the inner lead IL. In this embodiment, the lead frame LF in which the bending process was performed is prepared.

### Second Embodiment

The semiconductor device DEV4 according to the second embodiment will be described. Here, the differences from semiconductor device DEV1 will be mainly described, and repetitive descriptions will not be repeated.

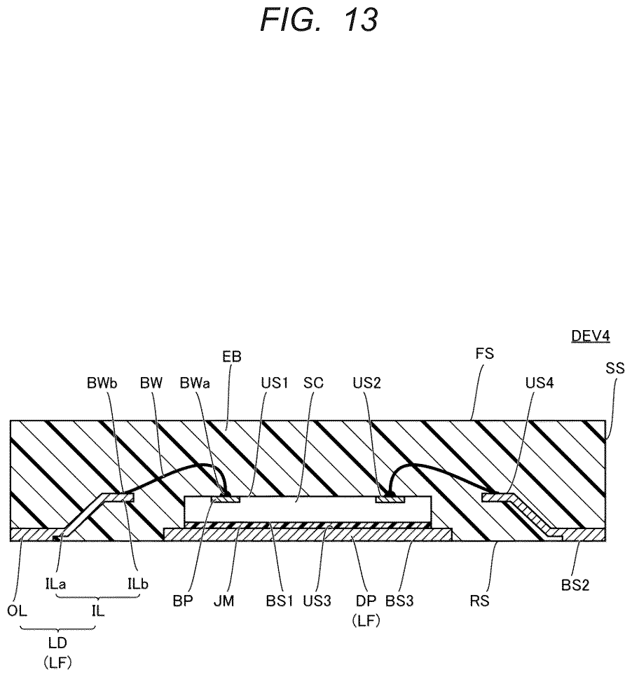

As shown in FIG. 13, a semiconductor device DEV4 includes a lead frame LF, a semiconductor chip SC, a bonding wire BW, and a sealing body EB. In the semiconductor device DEV4, the upper surface US2, to which the bonding wire BW is connected, of the bonding pad BP is located at the same height as the upper surface US4, to which the bonding wire BW is connected, of the inner lead IL. In this regard, the configuration of semiconductor device DEV4 is common with the configuration of semiconductor device DEV1.

In the semiconductor device DEV4, the lower surface (lower surface BS2) of the outer lead OL is exposed from the sealing body EB at the rear surface RS of the sealing body EB. That is, the semiconductor device DEV4 is QFN (Quad Flat Non-leaded package). In the semiconductor device DEV4, the tip end portion ILb is located over the base end portion ILa. That is, the tip end portion ILb is located closer to the front surface FS of the sealing body EB than the base end portion ILa. In the semiconductor device DEV4, the bonding wire BW (end portion BWb) is connected to the upper surface US4 located in the tip end portion ILb. As a result, in the semiconductor device DEV4, the upper surface US4, to which the bonding wire BW is connected, of the inner lead IL is located at the same height as the upper surface US2, to which the bonding wire BW is connected, of the bonding pad BP. In this regard, the configuration of semiconductor device DEV4 differs from the configuration of semiconductor device DEV1. Although the configuration in which the lower surface BS3 of the die pad DP is exposed from the sealing body EB at the rear surface RS of the sealing body EB has been described for the semiconductor device DEV4, the lower surface BS3 of the die pad DP may be covered by the sealing body EB as shown in the semiconductor device DEV1.

In the semiconductor device DEV4, the tip end portion ILb located over the base end portion ILa is obtained by performing a bending process to the inner lead IL. In the semiconductor device DEV4, since the upper surface US2, to which the bonding wire BW is connected, of the bonding pad BP is located at the same height as the upper surface US4, to which the bonding wire BW is connected, of the inner lead IL, the capillary contact angle when connecting the end portion BWa to the upper surface US2 and the capillary contact angle when connecting the end portion BWb to the upper surface US4 can both be set to 90°, and a good bond can be obtained at both the interface between the end portion BWa and the upper surface US2 and the interface between the end portion BWb and the upper surface US4.

Although the invention made by the inventor has been specifically described based on the embodiment, it is needless to say that the present invention is not limited to the above embodiment and various modifications can be made without departing from the gist thereof.

What is claimed is:

1. A semiconductor device comprising:
a semiconductor chip;
a die pad;
a lead; and
a bonding wire,
wherein the semiconductor chip has a first lower surface and a first upper surface opposite the first lower surface,
wherein the semiconductor chip has a bonding pad provided on the first upper surface,
wherein the bonding pad has a second upper surface,
wherein the die pad has a third upper surface,
wherein the lead has an outer lead and an inner lead,
wherein the inner lead has a fourth upper surface,
wherein the inner lead is connected to the outer lead,
wherein the semiconductor chip is mounted on the die pad such that the first lower surface faces the third upper surface,
wherein the bonding pad and the inner lead are electrically connected to each other via the bonding wire, and
wherein, in cross-sectional view, the second upper surface, to which the bonding wire is connected, of the bonding pad is located at the same height as the fourth upper surface, to which the bonding wire is connected, of the inner lead.

2. The semiconductor device according to claim 1, further comprising:
a bonding material interposed between the first lower surface of the semiconductor chip and the third upper surface of the die pad,
wherein a total thickness of the semiconductor chip and the bonding material is equal to a height difference between the third upper surface of the die pad and the fourth upper surface, to which the bonding wire is connected, of the inner lead.

3. The semiconductor device according to claim 1, further comprising:
a sealing body sealing the semiconductor chip, the die pad, the inner lead and the bonding wire,
wherein the sealing body has a side surface, and
wherein the outer lead protrudes from the side surface.

4. The semiconductor device according to claim 3,
wherein the die pad has a third lower surface,
wherein the sealing body has a front surface, a rear surface opposite the front surface, and the side surface located between the front surface and the rear surface,
wherein the third lower surface of the die pad is exposed from the sealing body at the rear surface of the sealing body,
wherein the inner lead has:
a base end portion connected to the outer lead; and
a tip end portion located closer to the rear surface of the sealing body than the base end portion in cross-sectional view, and
wherein the bonding wire is connected to the fourth upper surface in the tip end portion.

5. The semiconductor device according to claim 4, wherein the outer lead has a gull-wing shape.

6. The semiconductor device according to claim 1, further comprising:
a sealing body sealing the semiconductor chip, the die pad, the inner lead and the bonding wire,
wherein the sealing body has a rear surface,
wherein the outer lead has a second lower surface, and
wherein the second lower surface is exposed from the sealing body at the rear surface of the sealing body.

7. The semiconductor device according to claim 6,
wherein the sealing body has a front surface, the rear surface opposite the front surface, and a side surface located between the front surface and the rear surface,
wherein the inner lead has:
a base end portion connected to the outer lead; and
a tip end portion located closer to the rear surface of the sealing body than the base end portion in cross-sectional view, and
wherein the bonding wire is connected to the fourth upper surface in the tip end.

8. The semiconductor device according to claim 1, wherein the bonding wire is made of copper or a copper alloy.

9. A method of manufacturing a semiconductor device, comprising steps of:
(a) preparing a semiconductor chip having: a first lower surface, a first upper surface opposite the first lower surface, and a bonding pad having a second upper surface and provided on the first upper surface;
(b) preparing a lead frame including: a die pad having a third upper surface, and a lead including an inner lead having a fourth upper surface;
(c) mounting the semiconductor chip on the die pad such that the first lower surface faces the third upper surface; and
(d) electrically connecting the bonding pad and the inner lead to each other via a bonding wire by using a bonding apparatus,
wherein the bonding apparatus includes:
a bonding head;
a stage that is capable to move the bonding head in a horizontal plane;
a transducer having a first end portion and a second end portion, the first end portion being connected to the bonding head; and
a capillary connected to the second end portion of the transducer and holding the bonding wire,
wherein the bonding wire has one end portion and an other end portion,
wherein the step of (d) includes:
(d1) connecting the one end portion of the bonding wire to the second upper surface of the bonding pad,
(d2) after the (d1), moving the bonding head until the other end portion of the bonding wire is located on the fourth upper surface of the inner lead, while the second end portion of the transducer is moved in an arc motion such that an extending direction of the capillary is inclined with respect to a normal direction of the horizontal plane, and
(d3) after the (d2), connecting the other end portion of the bonding wire to the fourth upper surface of the inner lead, and
wherein the extending direction of the capillary is parallel to the normal direction when the one end portion of the bonding wire is connected to the second upper surface of the bonding pad and when the other end portion of the bonding wire is connected to the fourth upper surface of the inner lead.

10. The method according to claim 9,
wherein in the step of (c), a bonding material is interposed between the first lower surface of the semiconductor chip and the third upper surface of the die pad, and wherein in the step of (a), the semiconductor chip is selected such that a total thickness of the semiconductor chip and the bonding material is equal to a height difference between the third upper surface of the die pad and the fourth upper surface, to which the other end of the bonding wire is connected, of the inner lead.

11. The method according to claim 9,
wherein in the step of (c), a bonding material is interposed between the first lower surface of the semiconductor chip and the third upper surface of the die pad, and
wherein in the step of (b), the lead frame is selected such that a height difference between the third upper surface of the die pad and the fourth upper surface, to which the other end portion of the bonding wire is connected, of the inner lead is equal to a total thickness of the semiconductor chip and the bonding material.

12. The method according to claim 9,
wherein the semiconductor device further includes a sealing body sealing the semiconductor chip, the die pad, the inner lead and the bonding wire,
wherein the die pad has a third lower surface,
wherein the sealing body has a front surface, a rear surface opposite the front surface, and a side surface located between the front surface and the rear surface,
wherein the third lower surface of the die pad is exposed from the sealing body at the rear surface of the sealing body,
wherein the inner lead has: a base end portion; and a tip end portion,
wherein the lead has an outer lead connected to the inner lead,
wherein the base end portion is connected to the outer lead, and
wherein the lead frame prepared in the step of (b) is bent such that the tip end portion is located closer to the rear surface of the sealing body than the base end portion in cross-sectional view.

13. The method according to claim 9,
wherein the semiconductor device further includes a Sealing body sealing the semiconductor chip, the die pad, the inner lead and the bonding wire,
wherein the die pad has a third lower surface,
wherein the sealing body has a front surface, a rear surface opposite the front surface, and a side surface located between the front surface and the rear surface,
wherein the third lower surface of the die pad is exposed from the sealing body at the rear surface of the sealing body,
wherein the inner lead has: a base end portion; and a tip end portion,
wherein the lead has an outer lead connected to the inner lead,
wherein the base end portion is connected to the outer lead, and
wherein the lead frame prepared in the step of (b) is bent such that the tip end portion is located closer to the front surface of the sealing body than the base end portion in cross-sectional view.
